(19) United States
(12) Patent Application Publication
(10) Pub. No.: US 2021/0239621 A1
(43) Pub. Date: Aug. 5, 2021

(54) SOLDERABILITY, OXIDATION, AND CORROSION INDICATOR FOR SEMICONDUCTOR PACKAGES

(71) Applicant: Advanced Micro Devices, Inc., Santa Clara, CA (US)

(72) Inventor: Keith G. Newman, Santa Clara, CA (US)

(21) Appl. No.: 16/777,210

(22) Filed: Jan. 30, 2020

(51) Int. Cl. G01N 21/78; B01L 3/00

(52) U.S. Cl. CPC G01N 21/783; B01L 2300/025; B01L 2300/126; B01L 3/505

(57) ABSTRACT

An indicator card for determining solderability, oxidation, corrosion and/or reliable operability of semiconductor packages stored in moisture barrier bags is disclosed. The indicator card may include a reactive metal-containing layer on a non-reactive substrate. The reactive metal-containing layer may react with a destructive gas (e.g., an oxidizing gas or corrosive gas) to provide a visual indication of the amount of exposure to the destructive gas has been encountered by a semiconductor package while the semiconductor package is stored in a moisture barrier bag. The visual indication may indicate to a user whether the amount of exposure is above or below an exposure threshold where the exposure threshold differentiates between acceptable and unacceptable levels of exposure related to solderability, oxidation, corrosion and/or reliable operability of the semiconductor package.

### BACKGROUND

### Description of the Related Art

Semiconductor packages are often stored and/or transported in moisture barrier bags (MBBs). Some semiconductor packages may, for example, be stored for periods of a few years before the packages are assembled on a circuit board. Semiconductor packages are sealed in moisture barrier bags with the intent to prevent degradation of the packages while the packages are stored. The impact of shelf life on a package is currently addressed through the use of humidity indicator cards (HICs) that are sealed inside the moisture barrier bag along with the package. HICs are used to indicate the amount of moisture that the package has been exposed to while the package was stored in the moisture barrier bag before the package is used in any final board assembly. Exposure to excess moisture can lead to internal delamination of the package (e.g., “popcorning”) or other potentially catastrophic problems during board-level solder reflow processes. Thus, indication of exposure to excess moisture by the HICs may be used to prevent use of packages that are likely to fail in final board assemblies.

There are, however, other factors that need to be considered for semiconductor packages placed in storage using moisture barrier bags beyond excess moisture exposure. For instance, exposure to oxidizing and/or corrosive gases in the moisture barrier bag may reduce the solderability of a semiconductor package (such as a surface mount package), create open circuits or short circuits in the semiconductor package, and/or reduce semiconductor package reliability. Typically, exposure to oxidizing and/or corrosive gases is determined by analytical measurement (EDX, FTIR, XPS, Auger) of the semiconductor package surfaces, optical/SEM observation of the semiconductor package surfaces, or performing solder-reflow attachment of the semiconductor package to a circuit board and measuring electrical yield, assessing visual-mechanical defects, performing destructive mechanical strength analyses (shear, pull, torsion, bend) or conducting board-level reliability stress testing (temperature cycle, power cycle, monotonic bend, cyclic bend, drop, mechanical shock, vibration, etc.). Doing such measurements or testing, however, requires destructive use of production units, and takes time and resources in both taking the measurements and stopping any assembly until measurements are made. Because of these constraints, measurements to determine yield, oxidation, and/or corrosion are typically not conducted, or only conducted for a statistically small sample set, exposing the end-user to potential low-yield, poor quality and/or reduced reliability.

Thus, there is a need for providing a simple, quick, and effective way to determine the amount of exposure to oxidizing and/or corrosive gases for a semiconductor package placed in a moisture barrier bag. Being able to quickly and effectively determine whether the semiconductor package has been exposed to unacceptable levels of oxidizing and/or corrosive gases (e.g., levels that could limit or prevent solderability of the package or levels that may likely cause open or short circuits in exposed device circuitry) may improve reliability of a final assembly with the semiconductor package. For example, semiconductor packages that are indicated to have been exposed to unacceptable levels of oxidizing and/or corrosive gases may be removed from production assembly use or scrapped, while semiconductor packages that are indicated as not having been exposed to such levels may be more likely to produce reliable final assembly products.

### BRIEF DESCRIPTION OF THE DRAWINGS

Features and advantages of the methods and apparatus of the embodiments described in this disclosure will be more fully appreciated by reference to the following detailed description of presently preferred but nonetheless illustrative embodiments in accordance with the embodiments described in this disclosure when taken in conjunction with the accompanying drawings in which:

FIG. 1A-L depict representations of embodiments of semiconductor packages.

FIG. 2 depicts a representation of an embodiment of moisture barrier bag.

FIG. 3 depicts a representation of an embodiment of an indicator card.

FIG. 4 depicts a representation of multiple indicator cards.

FIG. 5 is a flow diagram illustrating a method for implementation of an indicator card, according to some embodiments.

### DETAILED DESCRIPTION OF THE EMBODIMENTS

In the following description, numerous specific details are set forth to provide a thorough understanding of the methods and mechanisms presented herein. However, one having ordinary skill in the art should recognize that the various embodiments may be practiced without these specific details. In some instances, well-known structures, configurations, materials, and techniques have not been shown in detail to avoid obscuring the approaches described herein. It will be appreciated that for simplicity and clarity of illustration, elements shown in the figures have not necessarily been drawn to scale. For example, the dimensions of some of the elements may be exaggerated relative to other elements.

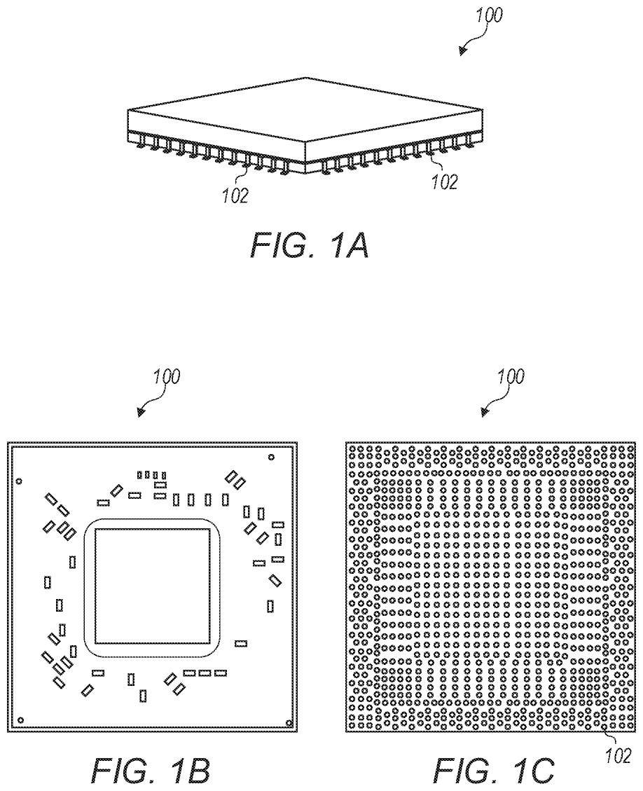

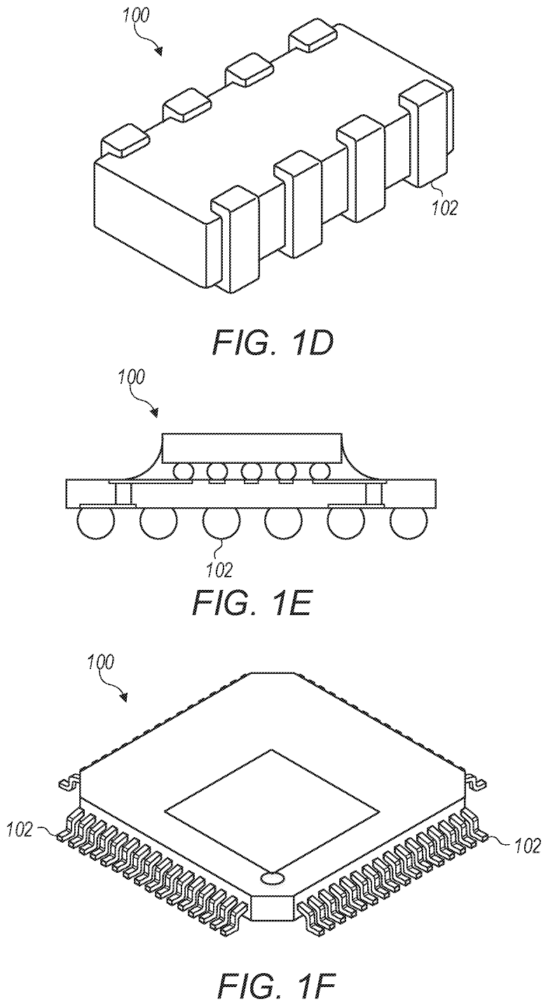

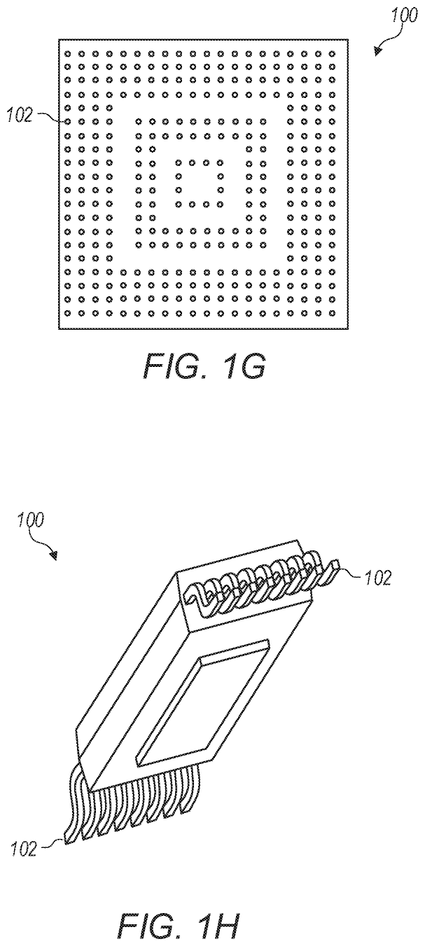

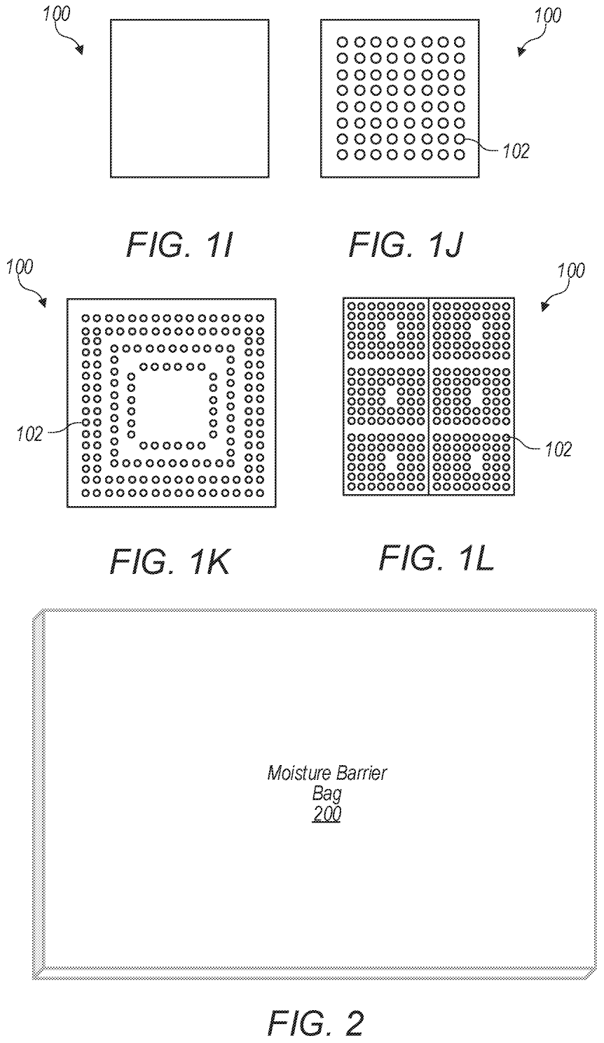

FIG. 1A depicts a representation of an embodiment of semiconductor package 100. Package 100 may include, for example, one or more integrated circuits and/or other semiconductor-based components. In certain embodiments, package 100 is a surface mount package (e.g., a ball grid assembly (BGA) package or a chip scale package (CSP)). For example, package 100 may include terminals 102 for attaching the package to a surface of another assembly such as a circuit board. In some embodiments, package 100 is a socketed package (e.g., a land grid array (LGA) package or a pin grid array (PGA) package). Examples of additional embodiments of semiconductor packages 100 are depicted in FIGS. 1B-1I. FIG. 1B depicts a top view representation of another embodiment of semiconductor package 100. FIG. 1C depicts a bottom view representation of the embodiment of semiconductor package 100 depicted in FIG. 1B. FIG. 1D depicts a representation of an embodiment of an array type semiconductor package. FIG. 1E depicts a representation of an embodiment of a CSP. FIG. 1F depicts a representation of an embodiment of a flatpack semiconductor package. FIG. 1G depicts a representation of an embodiment of a grid-array semiconductor package. FIG. 1H depicts a representation of an embodiment of a small outline semiconductor package. FIG. 1I depicts a top view representation of an embodiment of a flip chip CSP semiconductor package. FIG. 1J depicts a bottom view representation of the embodiment depicted in FIG. 1I. FIG. 1K depicts a representation of an embodiment of a wafer level CSP semiconductor package. FIG. 1L depicts a representation of another embodiment of a wafer level CSP semiconductor package.

Terminals 102 may be solder terminals or other terminals for connecting package 100 to an assembly (e.g., a printed circuit board assembly). In some embodiments, terminals 102 are part of a ball grid assembly (BGA). In embodiments using solder terminals on package 100, oxidation and/or corrosion of the terminals may affect the solderability of the package. For example, oxidation and/or corrosion on terminals 102 may reduce bonding effectiveness and/or increase electrical resistance of solder to terminal connections made during solder reflow processing.

Corrosion (and, in some instances, oxidation) may also affect external terminals or internal components in package 100. For example, corrosion may increase internal resistances of circuits in package 100, decrease resistance between terminals (e.g., leakage or shorts), or may cause degradation of internal components in the package. As corrosion may affect external terminals and/or internal components in the package, corrosion may be problematic for both surface mounted packages and socketed packages.

If semiconductor packages, such as package 100, are transported (e.g., sent to another location for assembly) or stored for long periods of time before assembly, oxidation and/or corrosion (along with moisture exposure) may reduce the yield and reliability of any final assembly made with the packages. Although semiconductor packages are typically dry packed in moisture barrier bags to reduce or inhibit the effects of moisture during storage, oxidation and/or corrosion in the packages during storage has not been monitored.

FIG. 2 depicts a representation of an embodiment of moisture barrier bag 200. Moisture barrier bag 200 may be made of materials that are substantially impermeable to protect the contents (e.g., package 100) in the bag. Materials for moisture barrier bag 200 may include, but not be limited to, metal foil, polyethylene, polyester, and combinations thereof. Bag 200 may be made of materials that combine to protect the contents of the bag against humidity, moisture, oxygen, airborne contaminants, and other contamination. In some embodiments, bag 200 includes static shielding materials. For example, bag 200 may include materials that protect the contents (e.g., package 100) against electrostatic discharge and electromagnetic interference.

In certain embodiments, bag 200 includes materials that are substantially impermeable to destructive gases. Destructive gases may include, but not be limited to, oxidizing gases and corrosive gases. An oxidizing gas may be, for example, oxygen or another gas capable of acting as an oxygen source. Examples of corrosive gases include, but are not limited to, sulfur, chlorine, bromine, and other halogen-based gases.

In certain embodiments, bag 200 is a sealable bag. The bag may be sealed, for example, using heat sealing of the opening in the bag. Heat sealing may fuse the materials together at the opening in bag 200 to close the opening and protect the contents in the bag. When bag 200 is heat sealed, the bag may be opened by tearing or cutting the bag open. In some embodiments, bag 200 may include a resealable opening such as a zipper or other reusable closure device. Resealable bags may, however, not be as effective at protecting contents inside the bag.

While moisture barrier bag 200 is used to protect contents in the bag from destructive gases, it can be possible that some destructive gases may either permeate the bag or be present during packaging of the bag (if, for example, the bag is not packed properly). These destructive gases may cause oxidation and/or corrosion of the contents in bag 200 such as package 100. As discussed above, oxidation and/or corrosion may reduce the solderability of package 100 and/or may degrade external terminals and/or internal components in the package. When package 100 is stored for any length of time in bag 200, it may be useful to determine whether the package has been exposed to any destructive gases and information on the amount of exposure. Determining the amount of exposure may be useful for determining the solderability of package 100 and whether the package will yield a reliable final assembly after solder reflow (with, for example, a printed circuit board), or for determining reliable electrical contact to package terminals for socketed packages.

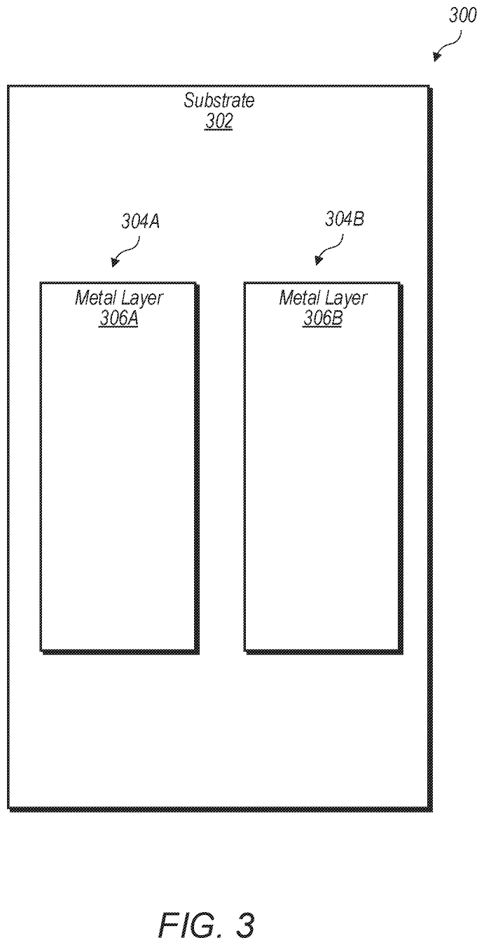

FIG. 3 depicts a representation of an embodiment of an indicator card. Indicator card 300 may be placed inside moisture barrier bag 200 along with package 100 to indicate an amount of exposure the package has had to destructive gases (e.g., oxidizing and/or corrosive gases) while the package has been inside the bag. For example, indicator card 300 may be placed in moisture barrier bag 200 along with package 100 and then the bag is sealed. When bag 200 is opened, indicator card 300 may be assessed to determine the amount of exposure of package 100 to destructive gases at the time of opening of the bag.

In certain embodiments, indicator card 300 includes substrate 302. Substrate 302 may be a non-reactive substrate. For example, substrate 302 may include paper, polymer, fabric, or combinations thereof. In certain embodiments, one or more reactive areas 304 (e.g., reactive area 304A and reactive area 304B) are formed on a surface of substrate 302. Reactive areas 304 may be formed on the surface of substrate 302 by methods such as, but not limited to, printing, embossing, laminating, or chemically depositing the reactive areas onto the surface of the substrate.

In certain embodiments, as shown in FIG. 3, reactive areas 304 include exposed metal layers 306 (e.g., metal layer 306A and metal layer 306B) formed on the surface of substrate 302. Metal layers 306 may be, for example, formed on the surface of substrate 302 as a foil, ink, paint, polymer, chemical compound. Examples of metals that may be used in metal layers 306 include elemental metals such as, but not limited to, silver, copper, tin, or combinations thereof.

In some embodiments, reactive areas 304 and metal layers 306 are configured to react with one or more destructive gases. Thus, indicator card 300 includes areas with surfaces that react to one or more destructive gases. In some embodiments, different reactive areas 304 react to different destructive gases. For example, reactive area 304A may react with oxidizing gases while reactive area 304B may react with corrosive gases. Individual reactive areas 304 may also be provided to react with different subsets of oxidizing and/or corrosive gases. For example, one reactive area may react with chlorine while another reactive area may react with bromine.

Reactive areas 304 and metal layers 306 may be formed such that the metal layers provide an indication of an amount of exposure to destructive gas that the metal layers have encountered. For example, reactive areas 304 and metal layers 306 may provide a visual indication of the amount of exposure that indicates whether the amount of exposure is above or below an exposure threshold. In some embodiments, the exposure threshold may be a threshold that differentiates between acceptable levels of exposure to the destructive gas and unacceptable levels of exposure to the destructive gas. In some embodiments, acceptable levels may be levels of exposure that allow for high-yield solder connection of package 100 (e.g., acceptable solderability) while unacceptable levels may be levels of exposure that might likely lead to unreliable soldering of the package. In some embodiments, acceptable levels may be levels of exposure that allow high-yield socket connection of package 100 while unacceptable levels may be levels of exposure that might likely lead to unreliable socket connections to the package. Another example of an exposure threshold may be a threshold that differentiates between acceptable corrosion levels in package 100 and unacceptable corrosion levels in the package. Unacceptable corrosion levels may be levels that reduce the operational reliability of package 100 below a determined amount.

In certain embodiments, the visual indication provided by metal layers 306 is a change in appearance of the metal layers. For example, the change in appearance may be a change in color of a metal layer, a change in shade of a metal layer, a change in finish of the metal layer, or combinations thereof. In some embodiments, the change in appearance includes a change in opacity of a metal layer.

For metal layers 306 to provide the visual indication on whether the amount of exposure is above or below the exposure threshold, the change in appearance of the metal layers may include a representation that is visible to a user (e.g., an assembly line operator). For example, metal layers 306 may have changes in greyscale, changes in patterns, or changes in colors that indicate to the user whether the amount of exposure is above or below the threshold. In some embodiments, the type of change may be dependent on the type of destructive gas that reacts with the metal layer.

One example of a change in metal layer 306 that may indicate to the user whether the amount of exposure is above or below the threshold may be a change in color from one color (e.g., blue) to another color (e.g., pink) when the amount of exposure exceeds the threshold. Another example of a change in metal layer 306 that may indicate to the user whether the amount of exposure is above or below the threshold may be a change in shade of silver from light gray to dark gray when the amount of exposure exceeds the threshold. Yet another example of a change in metal layer 306 that may indicate to the user whether the amount of exposure is above or below the threshold may be an emergence of a pattern on the metal layer when the amount of exposure exceeds the threshold. The emergent pattern may include, for example, letters or words that emerge or a specific pattern (such as a checkered pattern) that emerges when the amount of exposure exceeds the threshold.

In some embodiments, a change in metal layer 306 that indicates to the user whether the amount of exposure is above or below the threshold may include a non-visual indicator.

For example, the indicator may be a change in metal layer (such as an emergent pattern) that is visible under non-visible light conditions (e.g., as UV or IR light). In such embodiments, the user may have a non-visible light source available on the assembly line to inspect reactive areas 304 on indicator card 300.

As described above, metal layers 306 may include one or more metals that react with destructive gases to provide an indication on the amount of exposure to the destructive gases has occurred while indicator card 300 is placed in moisture barrier bag 200 along with package 100. The compositions of metal layers 306 may be selected based on the type of destructive gases that are desired to be monitored on indicator card 300 and the exposure thresholds that are determined for package 100. Thus, the compositions of metal layers 306 may vary depending on the desired implementation of indicator card 300.

Testing of the changes (e.g., reactivities) of different metal layers or combinations of metal layers to different destructive gases may be used to select desired metal layers for use on a specific implementation of indicator card 300. In some embodiments, testing may include exposing packages to different destructive gases and assessing the amounts of exposure that lead to various degrees of oxidation or corrosion in the tested packages. Testing of the packages may be correlated with testing of changes in different metal layers 306 on card 300 to generate a calibration standard for assessing the degree of oxidation or corrosion of a package. The calibration standard may include, for example, cards or other visual devices (e.g., photos or an application available on a device). The calibration standard may then be used to estimate an amount of oxidation or corrosion in a package based on a comparison of metal layers 306 on indicator card 300 to the calibration standard. In some embodiments, the comparison may be implemented using a camera or other optical inspection system.

In some embodiments, testing is used to determine what type of visual indication may be provided by different metal layers or combinations of metal layers in response to different destructive gases. In such embodiments, testing may be used to calibrate metal layers 306 to provide desired indication levels for desired exposure thresholds to selected destructive gases.

In certain embodiments, as shown in FIG. 3, indicator card 300 includes separate reactive areas 304 that may be used for indicating exposure to different destructive gases. In some embodiments, indicator card 300 may include a reactive area that includes an indication of moisture exposure (e.g., a humidity indicator card is included on indicator card 300). In some embodiments, indicator card 300 is used separately from a humidity indicator card (e.g., separate cards are both placed in a moisture barrier bag).

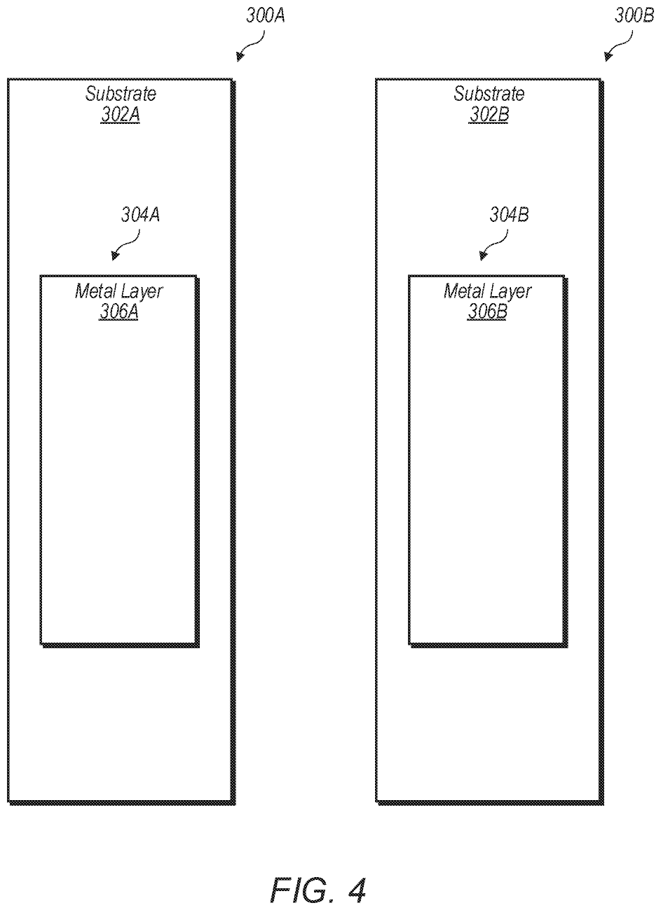

In some embodiments, multiple indicator cards are used to provide indication of exposure to destructive gases. FIG. 4 depicts a representation of multiple indicator cards 300A and 300B. In some embodiments, multiple indicator cards 300A and 300B may be used when substrate 302A is different from substrate 302B. Different substrates may be necessary, for example, when metal layer 306A requires a different substrate from metal layer 306B. In some embodiments, different substrates may be used to separate metal layer 306A and metal layer 306B when metal layer 306A is reactive with metal layer 306B.

As described above, indicator card 300 may provide a simple, quick, and effective indication for a user (e.g., an operator on an assembly line) to determine whether a semiconductor package (e.g., package 100) has been exposed to an amount of destructive gas that reduces the solderability or operability of the package below an acceptable level. Indicator card 300 may provide the indication without the need for additional measurement equipment such as surface analysis testing equipment. Indicator card 300 may allow the user to quickly make a determination on whether the semiconductor package is useable based on the visual indication on the card. The quick determination provided by indicator card 300 may improve efficiency of assembly of the semiconductor package into a final assembly by allow the user to determine the usability (e.g., solderability or operability) of the package without the need for additional testing or measurement, thus improving yield of the final assembly. In certain situations, indicator card 300 may be useful where packages have been stored in moisture barrier bags beyond their normal shelf life.

### Example Method

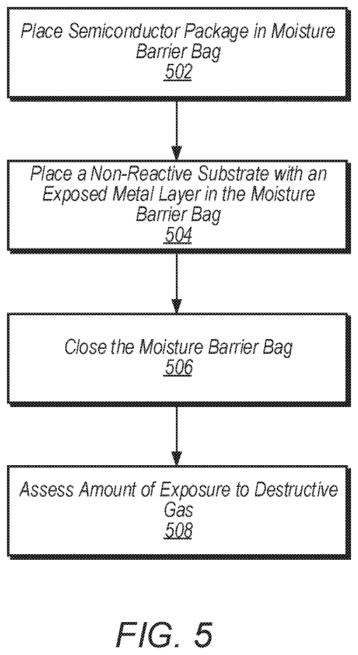

FIG. 5 is a flow diagram illustrating a method for implementation of indicator card 300, according to some embodiments. In various embodiments, some of the method elements shown may be performed concurrently, in a different order than shown, or may be omitted. Additional method elements may also be performed as desired.

At 502, in the illustrated embodiment, at least one semiconductor package may be placed in a moisture barrier bag.

At 504, in the illustrated embodiment, a non-reactive substrate with an exposed metal-containing layer on a surface of the substrate may be placed in the moisture barrier bag where the metal-containing layer includes at least one elemental metal that reacts with at least one destructive gas. In some embodiments, the at least one reactive metal-containing layer includes silver, copper, tin, or a combination thereof.

At 506, in the illustrated embodiment, the moisture barrier bag may be closed to enclose the at least one semiconductor package and the non-reactive substrate with the exposed metal-containing layer in the moisture barrier bag where the at least one reactive metal, while placed in the moisture barrier bag, reacts with the at least one destructive gas such that the exposed metal-containing layer provides a visual indication of an amount of reaction to the at least one destructive gas while the exposed metal-containing layer is in the moisture barrier bag, the visual indication being indicative of an amount of exposure to the at least one destructive gas of the at least one semiconductor package. In some embodiments, closing the moisture barrier bag includes sealing an opening of the moisture barrier bag.

At 508, in the illustrated embodiment, the amount of exposure to destructive gas by the at least one semiconductor package may be assessed by assessing the visual indication of the amount of reaction to the at least one destructive gas. In some embodiments, a solderability of the at least one semiconductor package is determined based on the determined amount of exposure. In some embodiments, the reliable terminal connection of the at least one socketed semiconductor package is determined based on the determined amount of exposure. In some embodiments, the amount of exposure is determined when the moisture barrier bag is opened.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

What is claimed:

1. An apparatus, comprising:
a non-reactive substrate configured to be placed in a moisture barrier bag along with at least one semiconductor package; and
an exposed metal-containing layer placed on a surface of the substrate, wherein the metal-containing layer includes at least one elemental metal that reacts with at least one destructive gas, and wherein the at least one elemental metal is configured to react with the at least one destructive gas such that the exposed metal-containing layer provides a visual indication of an amount of reaction to the at least one destructive gas while the exposed metal-containing layer is in the moisture barrier bag, the visual indication being indicative of an amount of exposure to the at least one destructive gas while the at least one semiconductor package is in the moisture barrier bag.

2. The apparatus of claim 1, wherein the substrate includes paper, polymer, fabric, or a combination thereof.

3. The apparatus of claim 1, wherein the exposed metal-containing layer is a foil, ink, paint, polymer, chemical compound or a combination thereof.

4. The apparatus of claim 1, wherein the at least one elemental metal includes silver, copper, tin, or a combination thereof.

5. The apparatus of claim 1, wherein the visual indication of the amount of reaction indicates whether the amount of exposure to the at least one destructive gas is above or below a threshold for exposure to the at least one destructive gas.

6. The apparatus of claim 5, wherein the threshold is a level of exposure that differentiates between acceptable levels of exposure to the at least one destructive gas and unacceptable levels of exposure to the at least one destructive gas.

7. The apparatus of claim 1, wherein the visual indication of the amount of reaction is a change in an appearance of the exposed metal-containing layer.

8. The apparatus of claim 7, wherein the change in the appearance includes a change in color, a change in shade, a change in finish, a change in opacity, or combinations thereof.

9. The apparatus of claim 1, wherein the visual indication of the amount of reaction includes a plurality of indicators for a plurality of destructive gases.

10. The apparatus of claim 1, wherein the at least one destructive gas is a corrosive gas or an oxidizing gas.

11. A method, comprising:
placing at least one semiconductor package in a moisture barrier bag;
placing a non-reactive substrate with an exposed metal-containing layer on a surface of the substrate in the moisture barrier bag, wherein the metal-containing layer includes at least one elemental metal that reacts with at least one destructive gas; and
closing the moisture barrier bag to enclose the at least one semiconductor package and the non-reactive substrate with the exposed metal-containing layer in the moisture barrier bag;
wherein the at least one elemental metal, while placed in the moisture barrier bag, reacts with the at least one destructive gas such that the exposed metal-containing layer provides a visual indication of an amount of reaction to the at least one destructive gas while the exposed metal-containing layer is in the moisture barrier bag, the visual indication being indicative of an amount of exposure to the at least one destructive gas of the at least one semiconductor package.

12. The method of claim 11, wherein the exposed metal-containing layer is a foil, ink, paint, polymer, chemical compound or a combination thereof.

13. The method of claim 11, wherein the at least one elemental metal includes silver, copper, tin, or a combination thereof.

14. The method of claim 11, further comprising assessing the visual indication of the amount of reaction to determine an amount of exposure to the at least one destructive gas by the at least one semiconductor package.

15. The method of claim 14, further comprising determining a solderability of the at least one semiconductor package based on the determined amount of exposure.

16. The method of claim 14, wherein the amount of exposure is determined when the moisture barrier bag is opened.

17. A system, comprising:
a moisture barrier bag;
at least one semiconductor package configured to be placed in the moisture barrier bag; and
a solderability, oxidation, and corrosion indicator card configured to be placed in the moisture barrier bag along with the at least one semiconductor package, wherein the solderability, oxidation, and corrosion indicator card comprises:
a non-reactive substrate; and
an exposed metal-containing layer placed on a surface of the substrate, wherein the metal-containing layer includes at least one elemental metal that reacts with at least one destructive gas, and wherein the at least one elemental metal is configured to react with the at least one destructive gas such that the exposed metal-containing layer provides a visual indication of an amount of reaction to the at least one destructive gas while the exposed metal-containing layer is in the moisture barrier bag, the visual indication being indicative of an amount of exposure to the at least one destructive gas while the at least one semiconductor package is in the moisture barrier bag.

18. The system of claim 17, wherein the visual indication of the amount of reaction indicates whether the amount of exposure to the at least one destructive gas is above or below a threshold for exposure of the at least one semiconductor package to the at least one destructive gas.

19. The system of claim 18, wherein the threshold is for exposure of the at least one semiconductor package to the at least one destructive gas is based on a level of exposure that determines whether the at least one semiconductor package has solderability.

20. The system of claim 17, wherein the at least one semiconductor package comprises at least one integrated circuit.
